(19) United States
(12) Patent Application Publication
(10) Pub. No.: US 2011/0180402 A1
(43) Pub. Date: Jul. 28, 2011

(54) Vacuum Processing Apparatus

(75) Inventors: Takaomi Kurata, Chiba (JP); Junya Kiyota, Chiba (JP); Makoto Arai, Chiba (JP); Yasuhiko Akamatsu, Chiba (JP); Satoru Ishibashi, Chiba (JP); Shin Asari, Chiba (JP); Kazuya Saito, Chiba (JP); Shigemitsu Sato, Kanagawa (JP); Masashi Kikuchi, Kanagawa (JP)

(73) Assignee: ULVAC, INC., Chigasaki-shi, Kanagawa (JP)

(21) Appl. No.: 13/122,584

(22) PCT Filed: Oct. 7, 2009
(86) PCT No.: PCT/JP2009/005227

§ 371 Date: Apr. 5, 2011

(30) Foreign Application Priority Data
Oct. 8, 2008 (JP) 2008-262085

(51) Int. Cl. C23C 14/34; B05C 11/00; B05C 13/00; C23C 16/44; H01L 21/336; C23C 14/08

(52) U.S. Cl. 204/298.23; 118/50; 118/719; 204/298.02

(57) ABSTRACT

To provide a vacuum processing apparatus capable of supporting and conveying a substrate by a method suitable for a processing content in each processing step and capable of suppressing various mechanisms provided within a processing chamber from being adversely affected. More particularly, the CVD chamber of the apparatus is configured to be horizontal, and hence the above-mentioned problem can be solved. Further, by configuring a sputtering apparatus as the vertical type processing apparatus, problems with abnormal electrical discharge can be solved.

### TECHNICAL FIELD

The present invention relates to a vacuum processing apparatus, for example, for processing under vacuum a glass substrate or the like to be used in a display or the like.

### BACKGROUND ART

A substrate for a display has been increased in size with an increase of the size of the screen of the display. Due to this, there has been conventionally proposed and commercialized a vertical type vacuum processing apparatus as an apparatus for processing the substrate. The vertical type vacuum processing apparatus serves to process the substrate with the substrate being substantially vertically supported. With the vertical type vacuum processing apparatus, even if the substrate is increased in size, it is possible to suppress an apparatus-installing area from increasing. Further, it is possible to suppress the substrate from being deformed (for example, see Patent Document 1).

Patent Document 1: Japanese Patent Application Laid-open No. 2007-39157

### SUMMARY

### Problem to be Solved by the Invention

On the other hand, in the vacuum processing apparatus for performing a process such as a CVD, specialty gas such as cleaning gas is often used. For example, in the above-mentioned vertical type vacuum processing apparatus, there are installed a specific supporting mechanism for vertically supporting the substrate, a conveying mechanism, and the like. In a case where the specialty gas is used in such an apparatus, there is a fear that the supporting mechanism, the conveying mechanism, and the like may be corroded due to the specialty gas. Regarding some processing contents, the apparatus is less adversely affected when processing the substrate with the substrate being horizontally supported.

In the above-mentioned circumstances, it is an object of the present invention to provide a vacuum processing apparatus capable of supporting and conveying a substrate by a method suitable for a processing content in each processing step and capable of suppressing various mechanisms provided within a processing chamber from being adversely affected.

### Means for Solving the Problem

In order to achieve the above-mentioned problem, a vacuum processing apparatus according to an embodiment of the present invention includes a horizontal type processing unit, a vertical type processing unit, and a change chamber.

The horizontal type processing unit is capable of keeping a vacuum state and processes a base material in a state in which the base material is horizontally oriented.

The vertical type processing unit is capable of keeping a vacuum state and processes the base material in a state in which the base material is oriented upright.

The change chamber is capable of keeping a vacuum state, is connected to the horizontal type processing unit and the vertical type processing unit, and changes a posture of the base material.

### BRIEF DESCRIPTION OF DRAWINGS

FIG. 1 is a schematic plan view showing a vacuum processing apparatus according to an embodiment of the present invention.

FIG. 2 is a schematic view showing a mechanism for changing the posture of a substrate in a posture changing chamber.

FIG. 3 is a flow chart showing a processing order for the substrate in the vacuum processing apparatus.

FIG. 4 are cross-sectional views of a main part in respective steps, which describe a method of manufacturing a field effect transistor according to the embodiment of the present invention.

FIG. 5 are cross-sectional views of the main part in respective steps, which describe the method of manufacturing a field effect transistor according to the embodiment of the present invention.

FIG. 6 are cross-sectional views of the main part in respective steps, which describe the method of manufacturing a field effect transistor according to the embodiment of the present invention.

FIG. 7 are cross-sectional views of the main part in respective steps, which describe the method of manufacturing a field effect transistor according to the embodiment of the present invention.

FIG. 8 are cross-sectional views of the main part in respective steps, which describe the method of manufacturing a field effect transistor according to the embodiment of the present invention.

FIG. 9 are schematic plan views respectively showing vacuum processing apparatuses according to other embodiments of the present invention.

### DETAILED DESCRIPTION

A vacuum processing apparatus according to an embodiment of the present invention includes a horizontal type processing unit, a vertical type processing unit, and a change chamber.

The horizontal type processing unit is capable of keeping a vacuum state and processes a base material in a state in which the base material is horizontally oriented.

The vertical type processing unit is capable of keeping a vacuum state and processes the base material in a state in which the base material is oriented upright.

The change chamber is capable of keeping a vacuum state, is connected to the horizontal type processing unit and the vertical type processing unit, and changes a posture of the base material.

Regarding some processing contents, the mechanisms and the like provided within the processing chamber are less adversely affected when the substrate is processed with the substrate being substantially horizontally supported in a horizontal type processing chamber.

The “state in which the base material is horizontally oriented” means a state in which the base material is kept substantially horizontal in such a degree that a horizontal type processing unit can perform a predetermined process.

The “state in which the base material is oriented upright” means a state in which the base material is kept substantially vertical in such a degree that a vertical type processing unit can perform a predetermined process.

The horizontal type processing unit may includes a first film-forming chamber for forming a first film, and a conveying chamber, which is connected to the first film-forming chamber and the change chamber, conveys the base material into the first film-forming chamber and the change chamber, and conveys the base material out of the first film-forming chamber and the change chamber. In this case, the vertical type processing unit may include a second film-forming chamber for forming a second film different from the first film, and a buffer chamber connected to the second film-forming chamber and the change chamber.

The horizontal type processing unit may be a cluster type processing unit including a plurality of processing chambers, the plurality of processing chambers including the first film-forming chamber, the plurality of processing chambers being arranged in the periphery of the conveying chamber.

The vertical type processing unit may be an in-line type processing unit in which a plurality of processing chambers including the second film-forming chamber are arranged in line.

The first film-forming chamber may be a CVD (Chemical Vapor Deposition) chamber.

In a CVD process, the specialty gas is used. Thus, the CVD chamber is configured as a horizontal apparatus, and hence it is possible to solve a problem that the supporting mechanism and the like for the base material are corroded due to the specialty gas, for example, in a case where the CVD chamber is configured as a vertical apparatus.

The CVD chamber is, for example, for forming at least one of a gate insulating film of a field effect transistor and a stopper layer formed on the active layer for protecting the active layer from etchant with respect to the active layer formed on the gate insulating film.

The second film-forming chamber may be the sputtering chamber.

In a case where a sputtering apparatus is configured as a horizontal apparatus, for example, when a target is arranged above the base material, there is a fear that the target material adhering to the periphery of the target may drop on the substrate with a result that the substrate may be contaminated. On the contrary, when the target is arranged under the base material, there is a fear that the target material adhering to a deposition preventing plate arranged in the periphery of the base material may drop on an electrode with a result that the electrode may be contaminated. There is a fear that, due to the above-mentioned contaminations, an abnormal electrical discharge may occur during the sputtering process. However, the sputtering chamber is configured as a vertical type processing chamber, and hence the above-mentioned problem can be solved.

The vertical type processing unit may include a sputtering chamber for forming, by sputtering, the active layer of the field effect transistor, which includes In—Ga—Zn—O-based composition, and for forming, on the active layer by sputtering, the stopper layer for protecting the active layer from the etchant with respect to the active layer.

The stopper layer is formed by the sputtering method, and hence it is possible to form the stopper layer without exposing the active layer to the atmosphere after the formation of the active layer. With this, it is possible to prevent film quality from being deteriorated due to the fact that moisture and impurities existing in the atmosphere adhere to the surface of the active layer. Further, after the formation of the active layer, the stopper layer is consecutively formed, and hence it is possible to reduce a processing time necessary for the formation of the stopper layer. Thus, it is possible to achieve an increase of the productivity.

In particular, in an embodiment of the present invention, within one sputtering chamber, the active layer and the stopper layer are consecutively formed, and hence it is possible to form the stopper layer without conveying the base material out of the film-forming chamber for the active layer. Thus, it is possible to achieve a further increase of the productivity. In this case, in the above-mentioned film-forming chamber, other than the sputtering target for forming the active layer, a sputtering target for forming stopper layer is arranged. Then, each of the sputtering targets is selected to be used depending on film-forming steps.

Alternatively, in place of one sputtering chamber, the vertical type processing unit may include a first sputtering chamber for forming, by sputtering, the active layer of the field effect transistor, which includes In—Ga—Zn—O-based composition, and a second sputtering chamber for forming, on the active layer by sputtering, the stopper layer for protecting the active layer from the etchant with respect to the active layer.

The vertical type processing unit may include a plurality of in-line type processing units.

With this, for example, in a case where one in-line type processing unit becomes unavailable due to required maintenance of the in-line type processing unit, another in-line type processing unit can be used instead.

In particular, in an embodiment of the present invention, it is advantageous if the in-line type processing unit includes the sputtering chamber and the horizontal type processing unit includes the CVD chamber. Self-cleaning with the cleaning gas can be performed in the CVD apparatus, while the self-cleaning with the cleaning gas cannot be performed in the sputtering apparatus. That is, the frequency of maintenance of the sputtering apparatus is higher than the frequency of maintenance of the CVD apparatus.

Hereinafter, embodiments of the present invention will be described with reference to the drawings.

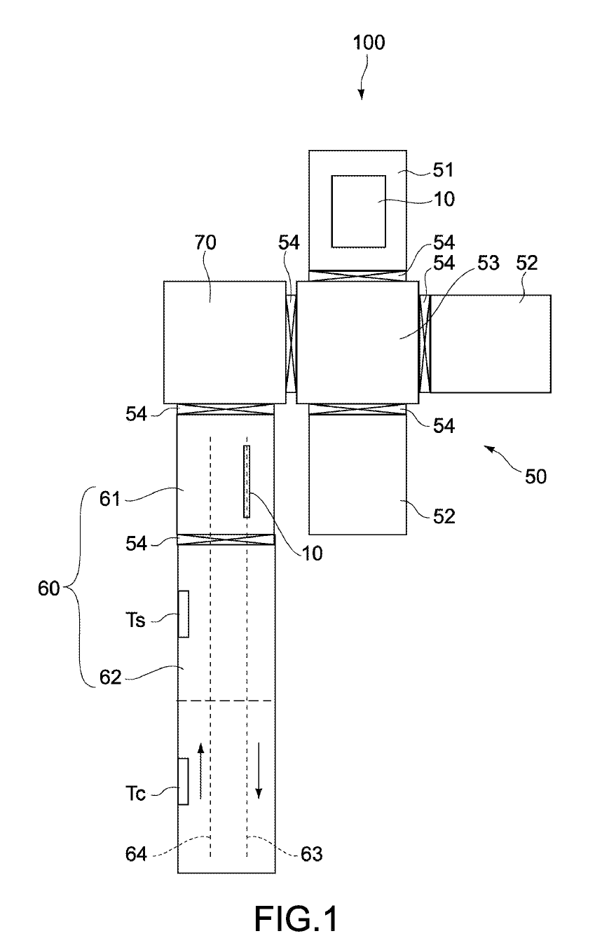

FIG. 1 is a schematic plan view showing a vacuum processing apparatus according to an embodiment of the present invention.

The vacuum processing apparatus 100 is an apparatus for processing a glass substrate (hereinafter, abbreviated as substrate) 10 to be used as a base material in a display, for example. Typically, the vacuum processing apparatus 100 is an apparatus responsible for a part of the manufacture of a field effect transistor having a so-called bottom gate type transistor structure.

The vacuum processing apparatus 100 includes a cluster type processing unit 50, an in-line type processing unit 60, and a posture changing chamber 70.

The cluster type processing unit 50 includes a plurality of horizontal type processing chambers. The plurality of horizontal type processing chambers process the substrate 10 in the state in which the substrate 10 is arranged substantially horizontally. Typically, the cluster type processing unit 50 includes a load lock chamber 51, a conveying chamber 53, and a plurality of CVD (Chemical Vapor Deposition) chambers 52.

The load lock chamber 51 switches between an atmospheric pressure state and a vacuum state, loads from the outside of the vacuum processing apparatus 100 the substrate 10, and unloads to the outside the substrate 10. The conveying chamber 53 includes a conveying robot (not shown). Each of the CVD chambers 52 is connected to the conveying chamber 53, and performs a CVD process with respect to the substrate 10. The conveying robot of the conveying chamber 53 carries the substrate 10 into the load lock chamber 51, each of the CVD chambers 52, and the posture changing chamber 70 to be described later. Further, the conveying robot of the conveying chamber 53 carries the substrate 10 out of each of the above-mentioned chambers.

In the CVD chambers 52, typically, a gate insulating film of the field effect transistor is formed.

It is possible to keep the conveying chamber 53 and the CVD chambers 52 under a predetermined degree of vacuum.

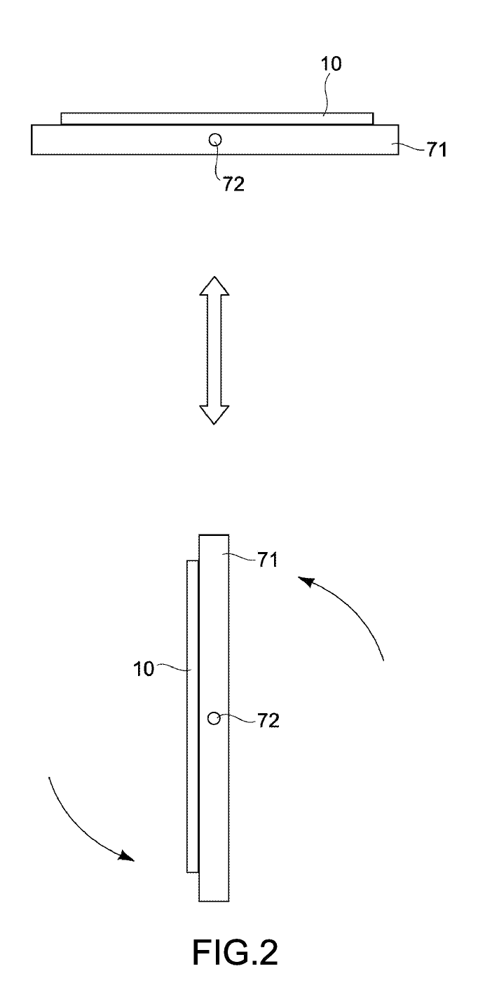

The posture changing chamber 70 changes the posture of the substrate 10 from the horizontal state to the vertical state and in turn, from the vertical state to the horizontal state. For example, as shown in FIG. 2, within the posture changing chamber 70, there is provided a holding mechanism 71 for holding the substrate 10.

The holding mechanism 71 is configured to be rotatable about a rotating shaft 72. The holding mechanism 71 holds the substrate 10 by use of a mechanical chuck, a vacuum chuck, or the like. The posture changing chamber 70 can be kept under substantially the same degree of vacuum as the conveying chamber 53.

By driving a driving mechanism (not shown) connected to the both ends of the holding mechanism 71, the holding mechanism 71 may be rotated.

The cluster type processing unit 50 may be provided with a heating chamber and other chambers for performing other processes in addition to the CVD chambers 52 and the posture changing chamber 70, which are connected to the conveying chamber 53.

The in-line type processing unit 60 includes a buffer chamber 61 and a sputtering chamber 62, and processes the substrate 10 in the state in which the substrate 10 is oriented substantially upright.

In the sputtering chamber 62, typically, as will be described later, a thin film having In—Ga—Zn—O-based composition (hereinafter, abbreviated as IGZO film) is formed on the substrate 10, and a stopper layer film is formed on that IGZO film. The IGZO film constitutes an active layer for the field effect transistor. The stopper layer film functions as an etching protection layer for protecting a channel region of the IGZO film from etchant in a step of patterning a metal film constituting a source electrode and a drain electrode and in a step of etching and removing an unnecessary region of the IGZO film. The sputtering chamber 62 includes a sputtering target Tc and a sputtering target Ts. The sputtering target Tc includes a target material for forming the IGZO film, and the sputtering target Ts includes a target material for forming the stopper layer film.

The in-line type processing unit 60 may be constituted of one or more sputtering chambers for forming a layer on a substrate passing through that chamber, or may be constituted of one or more sputtering chambers for forming a layer on a fixed substrate. In a case where a plurality of sputtering chambers are provided, gate valves (not shown) are respectively provided between the plurality of sputtering chambers. In the case where a plurality of sputtering chambers are provided, those are arranged in line.

Within the sputtering chamber 62 and the buffer chamber 61, there are prepared two conveying paths for the substrate 10, which are constituted of a forward path 63 and a return path 64, for example. Further, a supporting mechanism (not shown) is provided for supporting the substrate 10 in the state in which the substrate 10 is oriented upright or in the state in which the substrate 10 is slightly inclined from the upright state. Although, typically, a sputtering process is performed when the substrate 10 takes the return path 64, the sputtering process may be performed when the substrate 10 takes the forward path 63. The substrate 10 supported by the supporting mechanism is adapted to be conveyed through conveying rollers and a mechanism such as a rack-and-pinion mechanism, which are not shown. It is sufficient that the supporting mechanism, the conveying mechanism, a mechanism for passing and receiving the substrate 10 between the posture changing chamber 70 and the buffer chamber 61, and the like be publicly known mechanisms (for example, Japanese Patent Application Laid-open No. 2007-39157, Japanese Patent Application Laid-open No. 2008-202146, Japanese Patent Application Laid-open No. 2006-143462, Japanese Patent Application Laid-open No. 2006-114675, and the like).

Between the chambers, the gate valve 54 are respectively provided. The gate valves 54 are controlled independently of each other to be opened and closed.

The buffer chamber 61 is connected between the posture changing chamber 70 and the sputtering chamber 62. The buffer chamber 61 functions as a buffering region for pressurized atmosphere of the posture changing chamber 70 and pressurized atmosphere of the sputtering chamber 62. For example, when the gate valve 54 between the posture changing chamber 70 and the buffer chamber 61 is opened, the degree of vacuum of the buffer chamber 61 is controlled to be substantially equal to the pressure within the posture changing chamber 70. Alternatively, when the gate valve 54 between the buffer chamber 61 and the sputtering chamber 62 is opened, the degree of vacuum of the buffer chamber 61 is controlled to be substantially equal to the pressure within the sputtering chamber 62.

In the CVD chambers 52, in some cases, specialty gas such as cleaning gas is used for cleaning those chambers. For example, in a case where the CVD chambers 52 are configured as vertical type apparatuses, there is a fear that the supporting mechanism, the conveying mechanism, and the like, as provided in the sputtering chamber 62 as described above, which are peculiar to the vertical type apparatus, may be corroded due to the specialty gas, or the like. However, in the embodiment, the CVD chambers 52 are configured as the horizontal apparatuses, and hence the above-mentioned problem can be solved. Further, the buffer chamber 61 is capable of reliably separating the atmosphere of the CVD chambers 52 from the atmosphere of the sputtering chamber 62, and hence it is possible to solve the problem that the supporting mechanism, the conveying mechanism, and the like, as provided in the sputtering chamber 62 as described above, which are peculiar to the vertical type apparatus, may be corroded due to the specialty gas used in the CVD chambers 52, or the like.

For example, in a case where the sputtering apparatus is configured as a horizontal apparatus, for example, when the target is arranged above the substrate, there is a fear that the target material adhering to the periphery of the target may drop on the substrate with a result that the substrate 10 may be contaminated. On the contrary, when the target is arranged under the base material, there is a fear that the target material adhering to a deposition preventing plate arranged in the periphery of the substrate may drop on an electrode with a result that the electrode may be contaminated. There is a fear that, due to the above-mentioned contaminations, an abnormal electrical discharge may occur during the sputtering process. However, the sputtering chamber 62 is configured as a vertical type processing chamber, and hence the above-mentioned problem can be solved.

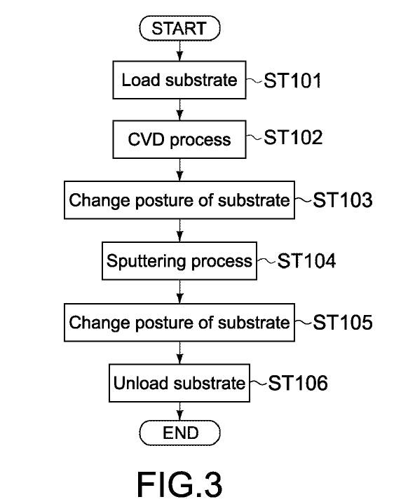

A processing order for the substrate 10 in the vacuum processing apparatus 100 configured in the above-mentioned manner will be described. FIG. 3 is a flow chart showing that order.

The substrate 10 loaded in the load lock chamber 51 (Step 101) is conveyed through the conveying chamber 53 into the CVD chambers 52, and a predetermined film, for example, a gate insulating film is formed on the substrate 10 by the CVD process (Step 102). After the CVD process, the substrate 10 is conveyed through the conveying chamber 53 into the posture changing chamber 70, and the posture of the substrate 10 is changed from the horizontal posture to the vertical posture (Step 103).

The substrate 10 in the vertical posture is conveyed through the buffer chamber 61 into the sputtering chamber 62, and is further conveyed through the forward path 63 up to the end of the sputtering chamber 62. After that, the substrate 10 takes the return path 64, and is subjected to the sputtering process with a result that a predetermined film, for example, an IGZO film and a stopper layer film are formed thereon (Step 104).

After the sputtering process, the substrate 10 is conveyed through the buffer chamber 61 into the posture changing chamber 70, and the posture of the substrate 10 is changed from the vertical posture to the horizontal posture (Step 105). After that, the substrate 10 is unloaded through the conveying chamber 53 and the load lock chamber 51 to the outside of the vacuum processing apparatus 100 (Step 106).

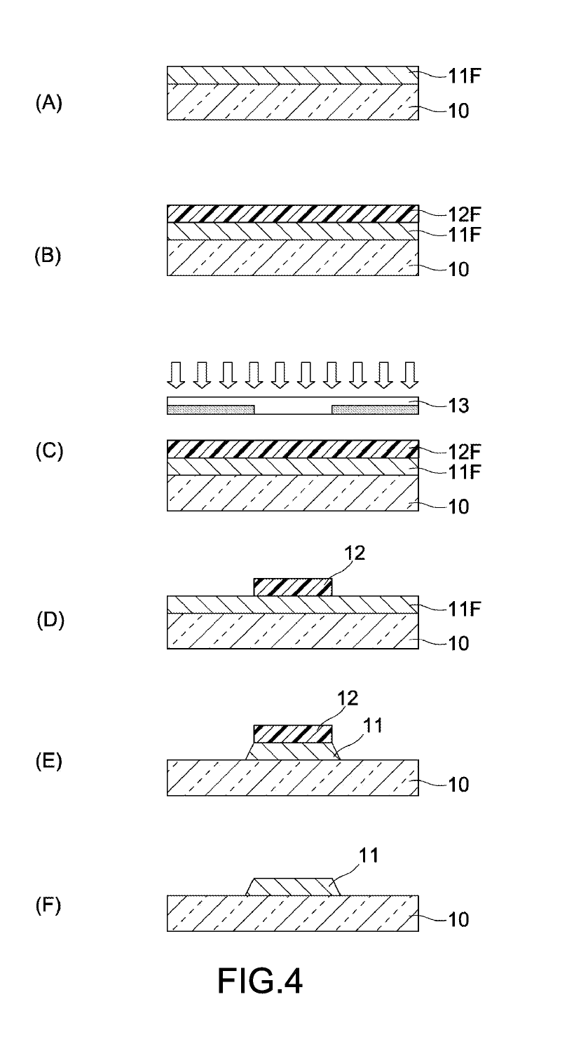

Next, a manufacturing method for the field effect transistor formed by utilizing the vacuum processing apparatus 100 configured in the above-mentioned manner will be described. FIG. 4 to FIG. 8 are cross-sectional views of a main part regarding respective steps of the manufacturing method. In the embodiment, the manufacturing method for the field effect transistor having the so-called bottom gate type transistor structure as described above.

First, as shown in FIG. 4(A), a gate electrode film 11F is formed on one surface of the substrate 10. The gate electrode film 11F is formed typically by a film-forming apparatus different from the vacuum processing apparatus 100. However, The gate electrode film 11F may be formed in the vacuum processing apparatus 100.

The gate electrode film 11F is formed of, typically, a single metal film or a metal multi-layer film of molybdenum, chromium, aluminum, or the like. The gate electrode film 11F is formed, for example, by the sputtering method. Although the thickness of the gate electrode film 11F is not particularly limited, the thickness of the gate electrode film 11F is, for example, 300 nm.

Next, as shown in FIGS. 4(B) to 4(D), a resist mask 12 for patterning the gate electrode film 11F into a predetermined shape is formed. This step includes a step of forming a photo-resist film 12F (FIG. 4(B)), an exposure step (FIG. 4(C)), and a development step (FIG. 4(D)).

The photo-resist film 12F is formed in such a manner that a photo-sensitive material in liquid state is applied on the gate electrode film 11F and then is dried. A dry film resist may be used as the photo-resist film 12F. The formed photo-resist film 12F is exposed to the light through an intermediation of a mask 13, and is developed. With this, the resist mask 12 is formed on the gate electrode film 11F.

Subsequently, as shown in FIG. 4(E), the gate electrode film 11F is subjected to etching by using the resist mask 12 as a mask therefor. In this manner, on the surface of the substrate 10, a gate electrode 11 is formed.

The etching method for the gate electrode film 11F is not particularly limited. Thus, a wet etching method may be employed or a dry etching method may be employed. After the etching, the resist mask 12 is removed. Although in order to remove the resist mask 12, an ashing process using a plasma of oxygen gas is applied, the method of removing the resist mask 12 is not limited thereto, and may be a melting and removing method using chemicals.

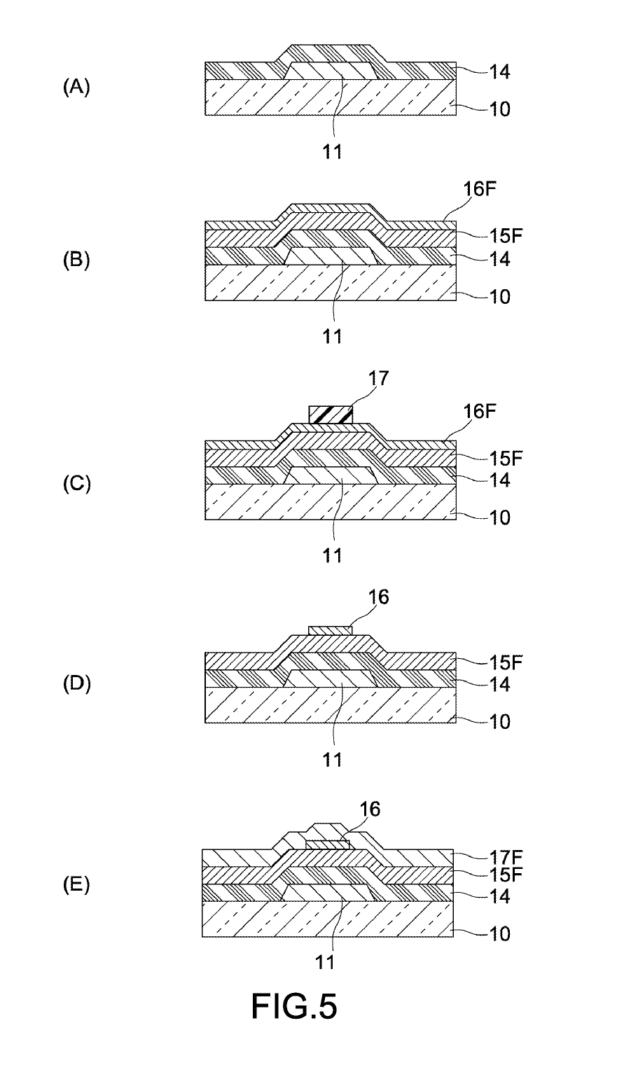

Next, as shown in FIG. 5(A), on the surface of the substrate 10, the gate insulating film 14 is formed so as to cover the gate electrode 11. The gate insulating film 14 is formed in the CVD chambers 52.

The gate insulating film 14 is formed of, typically, an oxide film or a nitride film such as a silicon oxide film (SiO₂) or a silicon nitride film (SiNx). The gate insulating film 14 is formed, for example, in the CVD chambers 52. The gate insulating film 14 may be formed by the sputtering method. Although the thickness of the gate electrode film 11F is not particularly limited, the thickness of the gate electrode film 11F ranges, for example, from 200 nm to 500 nm.

Subsequently, as shown in FIG. 5(B), on the gate insulating film 14, the IGZO film 15F and the stopper layer film 16F are formed in the stated order.

The IGZO film 15F and the stopper layer film 16F can be consecutively formed in the sputtering chamber 62. In this case, when a case where the sputtering target Tc for the IGZO film 15F and the sputtering target Ts for the stopper layer film 16F are provided in the same chamber, the IGZO film 15F and the stopper layer film 16F are independently of each other formed by switching the target to be used. Further, it is also possible that the IGZO film 15F be formed in the sputtering chamber 62 and that the stopper layer 16F be formed in the CVD chambers 52.

The IGZO film 15F is formed under a state in which the substrate 10 is heated at a predetermined temperature. In the embodiment, by a reactive sputtering method of sputtering a target in an oxygen gas atmosphere, to thereby deposit a reactant with oxygen above the substrate 10, an active layer 15 (IGZO film 15F) is formed. As an electrical discharge method, any of a DC electrical discharge, an AC electrical discharge, and an RF electrical discharge may be employed. Further, a magnetron discharge method in which a permanent magnet is arranged on a backside of the target may be employed.

The thickness of each of the IGZO film 15F and the stopper layer film 16F is not particularly limited. For example, the thickness of the IGZO film 15F ranges from 50 nm to 200 nm, and the thickness of the stopper layer film 16F ranges from 30 nm to 300 nm.

The IGZO film 15F constitutes the active layer (carrier layer) 15 of the transistor. The stopper layer film 16F functions as the etching protection layer for protecting the channel region of the IGZO film from etchant in the step of patterning the metal film constituting the source electrode and the drain electrode and in the step of etching and removing the unnecessary region of the IGZO film, which will be described later. The stopper layer film 16F is formed of SiO₂, for example.

Next, as shown in FIGS. 5(C) and 5(D), after a resist mask 17 for patterning the stopper layer film 16F into a predetermined shape is formed, the stopper layer film 16F is etched through an intermediation of the resist mask 17. In this manner, a stopper layer 16 is formed, which is opposed to the gate electrode 11 while sandwiching the gate insulating film 14 and the IGZO film 15F therebetween.

After the resist mask 17 is removed, as shown in FIG. 5(E), a metal film 17F is formed so as to cover the IGZO film 15F and the stopper layer 16.

The metal film 17F is formed of, typically, a single metal film or a metal multi-layer film of molybdenum, chromium, aluminum, or the like. The metal film 17F is formed, for example, by the film-forming apparatus different from the vacuum processing apparatus 100. However, the metal film 17F may be formed in the CVD chambers 52 of the vacuum processing apparatus 100. Although the thickness of the metal film 17F is not particularly limited, the thickness of the metal film 17F ranges, for example, from 100 nm to 500 nm.

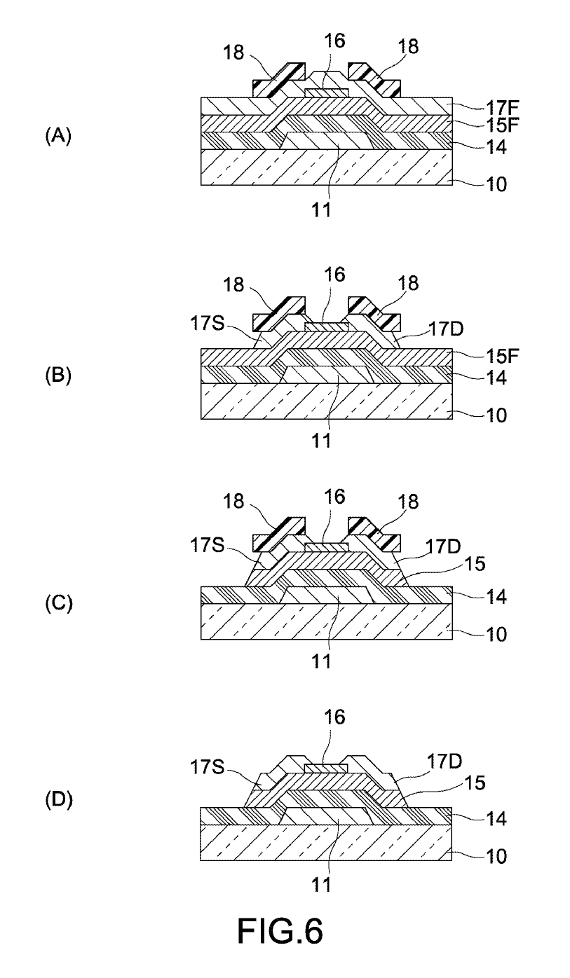

Subsequently, as shown in FIGS. 6(A) and 6(B), the metal film 17F is patterned.

The step of patterning the metal film 17F includes a step of forming a resist mask 18 (FIG. 6(A)) and a step of etching the metal film 17F (FIG. 6(B)). The resist mask 18 has a mask pattern with which a region directly on the stopper layer 16 and a peripheral region of individual transistor are to be opened. After the formation of the resist mask 18, the metal film 17F is etched by the wet etching method. In this manner, the metal film 17F is separated into the source electrode 17S and the drain electrode 17D. It should be noted that in the following, the source electrode 17S and the drain electrode 17D are also referred to as a source/drain electrode 17.

In the step of forming the source/drain electrode 17, the stopper layer 16 functions as an etching stopper layer for the metal film 17F. That is, the stopper layer 16 has a function of protecting the IGZO film 15F from etchant (for example, phosphoric-nitric-acetic acid) with respect to the metal film 17F. The stopper layer 16 is formed so as to cover a region of the IGZO film 15F between the source electrode 17S and the drain electrode 17D (hereinafter, referred to as “channel region”). Thus, the channel region of the IGZO film 15F is prevented from being affected by the step of etching the metal film 17F.

Next, as shown FIGS. 6(C) and 6(D), the IGZO thin film 15F is subjected to etching by using the resist mask 18 as a mask therefor.

The etching method is not particularly limited. Thus, the wet etching method may be employed or the dry etching method may be employed. By the step of etching the IGZO film 15F, the IGZO film 15F is isolated in elements, and the active layer 15 constituted of the IGZO film 15F is formed.

At this time, the stopper layer 16 functions as an etching protection film for a part of the IGZO film 15F, the part being located in the channel region. That is, the stopper layer 16 has a function of protecting the channel region, which is located directly under the stopper layer 16, from etchant (for example, oxalic acid series) with respect to the IGZO film 15F. Thus, the channel region of the active layer 15 is prevented from being affected by the step of etching the IGZO film 15F.

After the patterning of the IGZO film 15F, the resist mask 18 is removed from the source/drain electrode 17 by the ashing process or the like (FIG. 6(D)).

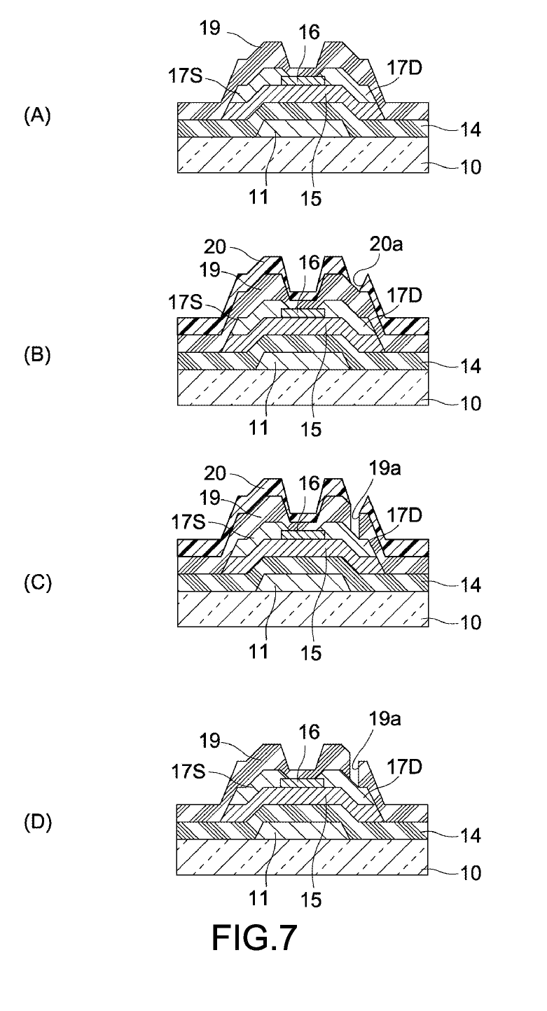

Next, as shown FIG. 7(A), above the surface of the substrate 10, a protective film (passivation film) 19 is formed so as to cover the source/drain electrode 17, the stopper layer 16, the active layer 15, and the gate insulating film 14.

The protective film 19 serves to cut off a transistor device including the active layer 15 from the air, to thereby ensure predetermined electrical and material properties. The protective film 19 is formed of, typically, an oxide film or a nitride film such as a silicon oxide film (SiO₂) or a silicon nitride film (SiNx). For example, the protective film 19 is formed by the CVD method or the sputtering method. Although the thickness of the protective film 19 is not particularly limited, the thickness of the protective film 19 ranges, for example, from 200 nm to 500 nm.

Subsequently, as shown FIGS. 7(B) to 7(D), a contact hole 19a communicating to the source/drain electrode 17 is formed in the protective film 19. This step includes a step of forming a resist mask 20 on the protective film 19 (FIG. 7(B)), a step of etching the protective film 19 exposed through an opening portion 20 of the resist mask 20 (FIG. 7(C)), and a step of removing the resist mask 20 (FIG. 7(D)).

Although for the formation of the contact hole 19a, the dry etching method is employed, or the wet etching method may be employed. Further, although the illustration is omitted, a contact hole communicating to the source electrode 17S is also formed at an arbitrate position.

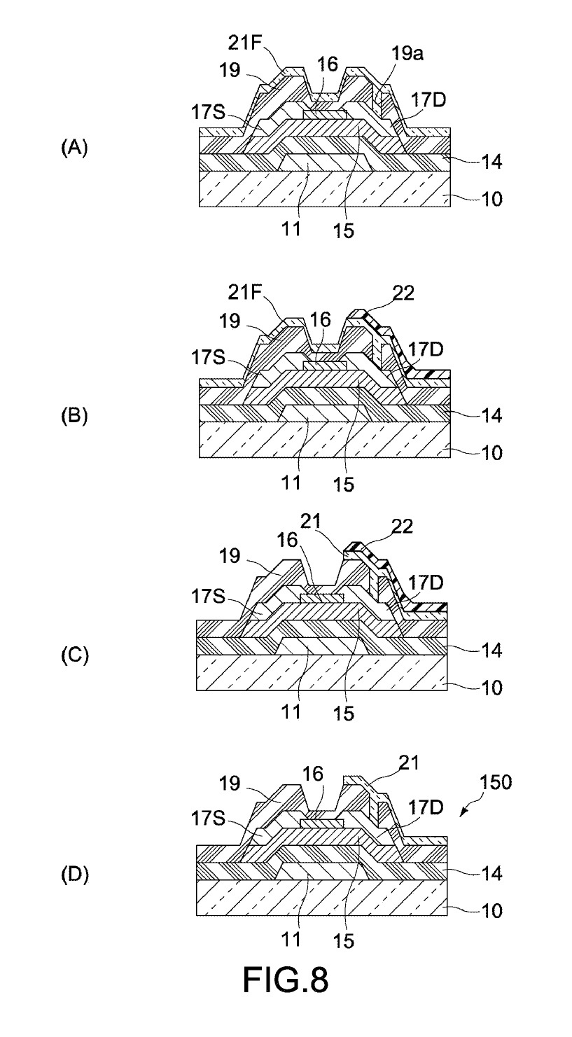

Next, as shown FIGS. 8(A) to 8(D), a transparent conductive film 21 is formed so as to come into contact with the source/drain electrode 17 through the contact hole 19a. This step includes a step of forming a transparent conductive film 21F (FIG. 8(A)), a step of forming a resist mask 22 on the transparent conductive film 21F (FIG. 8(B)), a step of etching a part of the transparent conductive film 21F, which is not covered with the resist mask 22 (FIG. 8(C)), and a step of removing the resist mask 20 (FIG. 8(D)).

The transparent conductive film 21F is formed of, typically, an ITO film or an IZO film. For example, the transparent conductive film 21F is formed by the sputtering method or the CVD method. Although for the etching of the transparent conductive film 21F, the wet etching method is employed, the etching method is not limited thereto, and the dry etching method may be employed.

At least one of the protective film 19 and the transparent conductive film 21F may be formed by the film-forming apparatus different from the vacuum processing apparatus 100, or may be formed by the vacuum processing apparatus 100.

A field effect transistor 150 in which the transparent conductive film 21 is formed, which is shown in FIG. 8(D), is subjected to an annealing step for the purpose of structural relaxation of the active layer 15. In this manner, desired transistor properties are provided to the active layer 15.

In the above-mentioned manner, the field effect transistor 150 is manufactured.

As described above, the stopper layer 16 is formed by the sputtering method, and hence it is possible to form the stopper layer 16 without exposing the active layer 15 to the atmosphere after the formation of the active layer 15. With this, it is possible to prevent film quality from being deteriorated due to the fact that moisture and impurities existing in the atmosphere adhere to the surface of the active layer 15. Further, after the formation of the active layer 15, the stopper layer 16 is consecutively formed, and hence it is possible to reduce a processing time necessary for the formation of the stopper layer 16. Thus, it is possible to achieve an increase of the productivity.

In particular, in a case where within one sputtering chamber 62, the active layer 15 and the stopper layer 16 are consecutively formed, it is possible to form the stopper layer 16 without conveying the base material out of the film-forming chamber for the active layer 15. Thus, it is possible to achieve a further increase of the productivity.

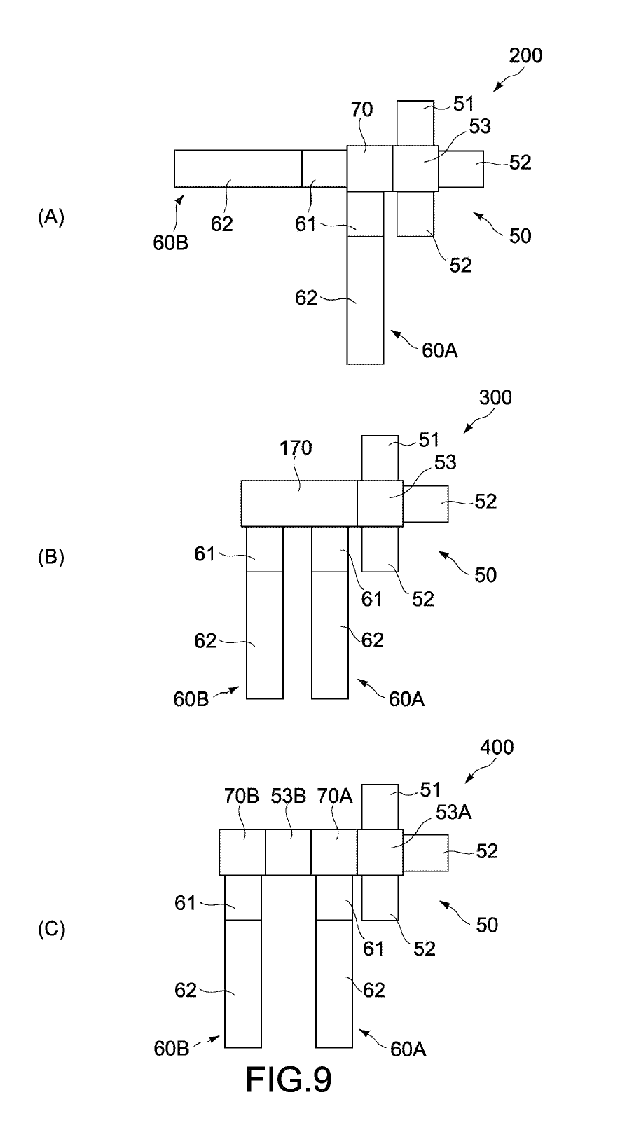

FIGS. 9(A) to 9(C) are schematic plan views showing vacuum processing apparatuses according to other embodiments of the present invention. In the following, the description of the same points in terms of members, functions, and the like included in the vacuum processing apparatus 100 according to the embodiment shown in FIG. 1 and the like will be simplified or omitted, and mainly the different points will be described.

Each of the vacuum processing apparatuses 200, 300, 400 according to the embodiments shown in FIGS. 9(A) to 9(C) includes a plurality of in-line type processing units. For example, in a case where one in-line type processing unit 60A becomes unavailable due to required maintenance of the in-line type processing unit 60A, another in-line type processing unit 60B can be used instead.

In particular, it is advantageous if the in-line type processing unit includes the sputtering chamber 62 and the cluster type processing unit 50 includes the CVD chambers 52. Self-cleaning with the cleaning gas can be performed in the CVD apparatus, while the self-cleaning with the cleaning gas cannot be performed in the sputtering apparatus. That is, the frequency of maintenance of the sputtering apparatus is higher than the frequency of maintenance of the CVD apparatus, and hence this embodiment becomes advantageous.

In a vacuum processing apparatus 200 shown in FIG. 9(A), for example, two in-line type processing units 60A and 60B, each of which is constituted of the buffer chamber 61 and the sputtering chamber 62, are connected to two side surfaces of one posture changing chamber 70, respectively. In this case, it is sufficient that the holding mechanism 71 (see FIG. 2) for the substrate 10, which is provided in the posture changing chamber 70, be configured to be rotated by a mechanism (not shown) within a predetermined angle, for example, 90° in the plane.

In the vacuum processing apparatus 200 shown in FIG. 9(A), to another side surface of the posture changing chamber 70, a third in-line type processing unit may be connected.

In a vacuum processing apparatus 300 shown in FIG. 9(B), a posture changing chamber 170 is formed so as to be long in one direction, and, for example, two in-line type processing units 60A and 60B are connected to the posture changing chamber 70 in such a manner that the in-line type processing units 60A and 60B are arranged in parallel to each other. In this case, it is sufficient that the holding mechanism 71 for the substrate 10, which is provided in the posture changing chamber 170, be configured to be moved by a mechanism (not shown) in a direction in which the in-line type processing units 60 are arranged. With this, the substrate 10 held by the holding mechanism 71 can be conveyed to both buffer chambers 61.

A vacuum processing apparatus 400 shown in FIG. 9(C) includes, for example, a first posture changing chamber 70A connected to a first conveying chamber 53A connected to the load lock chamber 51, a second conveying chamber 53B connected to the first posture changing chamber 70A, and a second posture changing chamber 70B connected to the second conveying chamber 53 B. Further, for example, two in-line type processing units 60A and 60B are connected to the first and second posture changing chambers 70A and 70B in such a manner that the in-line type processing units 60A and 60B are arranged in parallel to each other. It is sufficient that each of the first conveying chamber 53A and the second conveying chamber 53B include the similar conveying robot.

Even in each of the vacuum processing apparatuses 100 shown in FIGS. 9(B) and 9(C), three or more in-line type processing units may be connected to the posture changing chamber 170 or the posture changing chambers 70A and 70B.

The embodiments of the present invention are not limited to the above-mentioned embodiments, and various other embodiments are conceivable.

Although in the cluster type processing unit 50, the configuration in which the CVD chambers 52 are provided is employed, in place of the CVD chambers 52 or in addition to the CVD chambers 52, the sputtering chambers may be provided.

In the in-line type processing unit 60, the configuration in which the sputtering chamber 62 is provided. However, in the in-line type processing unit 60, in addition to the sputtering chamber 62, a chamber for forming a film by a PVD (Physical Vapor Deposition) method other than the sputtering method, a heating processing chamber, or the like may be provided in line.

The vacuum processing apparatus 100 according to each of the above-mentioned embodiments is capable of also manufacturing a field effect transistor other than the field effect transistor shown in FIG. 4 to FIG. 8. For example, the stopper layer 16 has, in addition to the function as the etching mask for the IGZO film 15F, a function as an insulator film for keeping electrical insulation between the source electrode 17S and the drain electrode 17D on an upper layer side of the active layer 15. However, the silicon oxide film constituting the stopper layer 16 is incapable of sufficiently preventing the incorporation of impurities from the atmosphere in some cases. When impurities from the atmosphere is mixed in the active layer 15, the transistor property is varied. In view of this, the stopper layer 16 may have a multi-layer structure composed of a first insulation film and a second insulation film. In this case, typically, the stopper layer 16 is set to have a two-layer structure composed of a first insulation film formed of a silicon oxide film or a silicon nitride film and of a second insulation film of a metal oxide film formed on the first insulation film. A desired electrical insulation property can be ensured due to the first insulation film, and a barrier property against the incorporation of impurities from the atmosphere can be ensured due to the second insulation film.

It is sufficient that, in order to manufacture the stopper layer 16 having the two-layer structure as described above, each of the above-mentioned vacuum processing apparatuses include two sputtering targets for the first and second insulation films in the sputtering chambers 62, for example.

Each of the above-mentioned vacuum processing apparatuses is capable of also manufacturing still another field effect transistor, for example, a field effect transistor in which the gate insulating film 14 is formed of two-layer structure of a first gate insulating film and a second gate insulating film. The gate insulating film is formed for the purpose of ensuring the electrical insulation between the gate electrode and the active layer. However, the gate insulating film formed of the silicon oxide film has a low barrier property against the diffusion of impurities from the substrate 10, and hence, due to the diffusion in the gate insulating film of impurities from the substrate 10, a predetermined insulation function may not be ensured. In this case, it becomes impossible to obtain the desired insulation function in the gate insulating film, and hence there is a fear that a gate threshold voltage may be varied or electrical leak with respect to the active layer may occur. In view of this, the gate insulating film 14 is set to have a two-layer structure of composed the first gate insulating film formed of a metal oxide film, and of the second gate insulating film of the silicon oxide film or the silicon nitride film formed on the first gate insulating film. A desired barrier property can be ensured due to the first gate insulating film, and a desired electrical insulation property can be ensured due to the second gate insulating film.

The first and second gate insulating films may be respectively formed in the two CVD chambers 52 of each of the above-mentioned vacuum processing apparatuses. Alternatively, the first and second gate insulating films may be respectively formed in the sputtering chambers 62.

For the first gate insulating film, an insulating metal oxide having a high barrier property against the diffusion of impurities from the substrate 10 is used. The first gate insulating film can be made of tantalum oxide (TaOx), alumina (Al₂O₃), yttria (Y₂O₃), or the like. When the first gate insulating film is formed on a lower layer side of the second gate insulating film, the gate insulating film excellent in the barrier property against the diffusion of impurities from the substrate 10 is formed. With this, it is possible to stably manufacture transistor devices each having a desired transistor property.

It should be noted that the first gate insulating film may be formed of the silicon oxide film or the silicon nitride film, and the second gate insulating film may be formed of the metal oxide film. Even with the above-mentioned configuration, the same effects as described above can be obtained.

What is claimed is:

1. A vacuum processing apparatus, comprising:
a horizontal type processing unit, which is capable of keeping a vacuum state and processes a base material in a state in which the base material is horizontally oriented;
a vertical type processing unit, which is capable of keeping a vacuum state and processes the base material in a state in which the base material is oriented upright; and
a change chamber, which is capable of keeping a vacuum state, is connected to the horizontal type processing unit and the vertical type processing unit, and changes a posture of the base material.

2. The vacuum processing apparatus according to claim 1, wherein
the horizontal type processing unit includes
a first film-forming chamber for forming a first film, and
a conveying chamber, which is connected to the first film-forming chamber and the change chamber, conveys the base material into the first film-forming chamber and the change chamber, and conveys the base material out of the first film-forming chamber and the change chamber, and
the vertical type processing unit includes
a second film-forming chamber for forming a second film different from the first film, and
a buffer chamber connected to the second film-forming chamber and the change chamber.

3. The vacuum processing apparatus according to claim 2, wherein
the horizontal type processing unit is a cluster type processing unit including a plurality of processing chambers, the plurality of processing chambers including the first film-forming chamber, the plurality of processing chambers being arranged in the periphery of the conveying chamber.

4. The vacuum processing apparatus according to claim 2, wherein
the vertical type processing unit is an in-line type processing unit in which a plurality of processing chambers including the second film-forming chamber are arranged in line.

5. The vacuum processing apparatus according to claim 2, wherein
the first film-forming chamber is a CVD (Chemical Vapor Deposition) chamber.

6. The vacuum processing apparatus according to claim 5, wherein
the CVD chamber is for forming at least one of a gate insulating film and a stopper layer of a field effect transistor, the stopper layer being formed on the active layer for protecting the active layer from etchant with respect to the active layer formed on the gate insulating film.

7. The vacuum processing apparatus according to claim 2, wherein
the second film-forming chamber is the sputtering chamber.

8. The vacuum processing apparatus according to claim 1, wherein
the vertical type processing unit includes a sputtering chamber for forming, by sputtering, an active layer of a field effect transistor, which has In—Ga—Zn—O-based composition, and for forming, on the active layer by sputtering, a stopper layer of the field effect transistor for protecting the active layer from the etchant with respect to the active layer.

9. The vacuum processing apparatus according to claim 1, wherein
the vertical type processing unit includes
a first sputtering chamber for forming, by sputtering, an active layer of a field effect transistor, which has In—Ga—Zn—O-based composition, and
a second sputtering chamber for forming, on the active layer by sputtering, a stopper layer of the field effect transistor for protecting the active layer from the etchant with respect to the active layer.

10. The vacuum processing apparatus according to claim 1, wherein
the vertical type processing unit includes a plurality of in-line type processing units.
